(19) United States
(12) Patent Application Publication
(10) Pub. No.: US 2025/0287552 A1
(43) Pub. Date: Sep. 11, 2025

(54) COOLANT FLOW RATE CONTROL METHOD AND SERVER CABINET

(71) Applicant: Wiwynn Corporation, New Taipei City (TW)

(72) Inventors: Tsung-Han Li, New Taipei City (TW); Yi Cheng, New Taipei City (TW); Tsung-Yi Chen, New Taipei City (TW)

(21) Appl. No.: 18/813,242

(22) Filed: Aug. 23, 2024

(30) Foreign Application Priority Data
Mar. 8, 2024 (TW) 113108708

(51) Int. Cl. H05K 7/20; G05D 16/00; G05D 16/20

(52) U.S. Cl. CPC H05K 7/20836; G05D 16/028; G05D 16/208; H05K 7/20781

(57) ABSTRACT

A coolant flow rate control method, configured to be applied to a plurality of servers and a fluid driver in fluid communication with the plurality of servers. The coolant flow rate control method includes setting a predetermined pressure difference between inlets and outlets of the plurality of servers based on power data of the plurality of servers and adjusting a duty ratio of the fluid driver for maintaining an actual pressure difference between the inlets and the outlets of the plurality of servers to match the predetermined pressure difference.

### CROSS-REFERENCE TO RELATED APPLICATIONS

This non-provisional application claims priority under 35 U.S.C. § 119(a) on Patent Application No(s). 113108708 filed in Taiwan, R.O.C. on Mar. 8, 2024, the entire contents of which are hereby incorporated by reference.

### TECHNICAL FIELD

The disclosure relates to a coolant flow rate control method and a server cabinet.

### BACKGROUND

Currently, servers in a cabinet are cooled by liquid cooling means. For example, in addition to a plurality of servers, there may be a fluid driver disposed in the cabinet. The fluid driver can drive a coolant to pass through the servers and carry away heat generated by heat sources (e.g. central processing units) in the servers. The existing fluid driver drives the coolant at a constant flow rate.

In general, the servers in the cabinet may be removed from the cabinet for maintenance. As the number of servers in the cabinet decreases, the flow rate of the coolant passing through each server may increase, which overly cools the remaining servers and increases an overall impedance. Therefore, in order to keep the coolant flowing at the set flow rate, the fluid driver needs to operate at a higher RPM (revolutions per minute), thereby increasing the power consumption.

### SUMMARY

One embodiment of this disclosure provides a coolant flow rate control method, configured to be applied to a plurality of servers and a fluid driver in fluid communication with the servers. The coolant flow rate control method includes: setting a predetermined pressure difference between inlets and outlets of the servers based on power data of the servers, and adjusting a duty ratio of the fluid driver for maintaining an actual pressure difference between the inlets and the outlets of the servers to match the predetermined pressure difference.

Another embodiment of this disclosure provides a server cabinet. The server cabinet includes a plurality of servers, a fluid driver, and a main controller. The servers are connected in parallel to each other, and each of the servers has an inlet and an outlet. The fluid driver is in fluid communication with the servers. The main controller is electrically connected to the fluid driver. The main controller is configured to set a predetermined pressure difference between the inlets and the outlets of the servers based on power data of the servers, and adjust a duty ratio of the fluid driver for maintaining an actual pressure difference between the inlets and the outlets of the servers to match the predetermined pressure difference.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a schematic diagram of a server cabinet according to a first embodiment of the disclosure;

FIG. 2 is a flowchart of a coolant flow rate control method cooperated with the server cabinet in FIG. 1;

FIG. 3 is a schematic diagram of the server cabinet in FIG. 1 when one of the servers is removed;

FIG. 4 is a schematic diagram of a server cabinet according to a second embodiment of the disclosure;

FIG. 5 is a flowchart of a coolant flow rate control method cooperated with the server cabinet in FIG. 4;

FIG. 6 is a schematic diagram of a server cabinet according to a third embodiment of the disclosure; and

FIG. 7 is a flowchart of a coolant flow rate control method cooperated with the server cabinet in FIG. 6.

### DETAILED DESCRIPTION

Firstly, note that, in the drawings, a thin line connects two components, which indicates that the two components are electrically connected to each other; that is, signals can be transmitted between them. Moreover, a thick arrow connects two components, which indicates that the two components are in fluid communication with each other and illustrates the flowing direction of fluid between them.

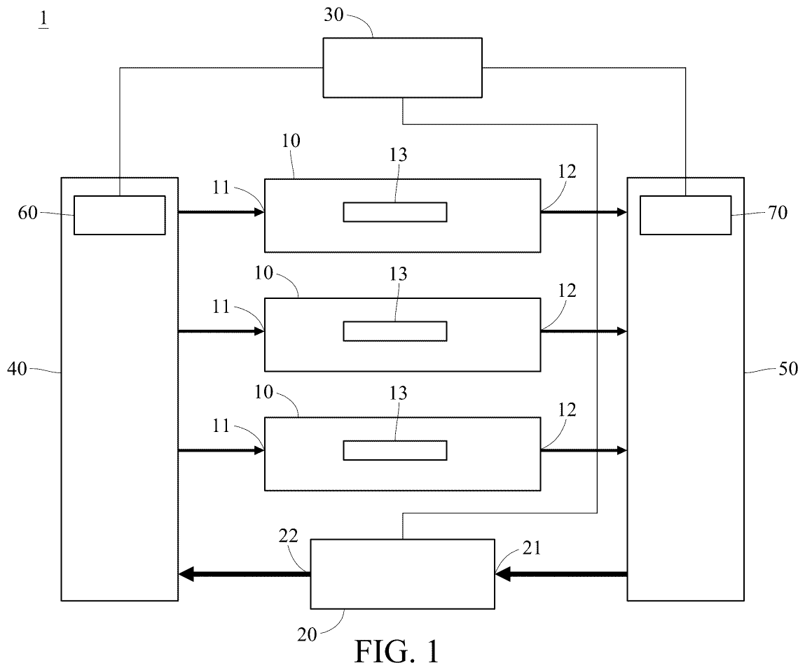

Referring to FIG. 1. FIG. 1 is a schematic diagram of a server cabinet according to a first embodiment of the disclosure.

In this embodiment, the server cabinet 1 includes a plurality of servers 10, a fluid driver 20, and a main controller 30. In addition, the server cabinet 1 may include a cabinet. The server 10, the fluid driver 20, and the main controller 30 are disposed in the cabinet. In order to clearly show the connection relationship among the server 10, the fluid driver 20, and the main controller 30, the cabinet is omitted in FIG. 1.

These servers 10 are connected in parallel to each other, and the fluid driver 20 is in fluid communication with these servers 10. Furthermore, server cabinet 1 may include a first manifold 40 and a second manifold 50. Each of these servers 10 has an inlet 11 and an outlet 12. In addition, the fluid driver 20 also has an inlet 21 and outlet 22. The outlet 22 of the fluid driver 20 is in fluid communication with the inlets 11 of these servers 10 through the first manifold 40, and the inlet 21 of the fluid driver 20 is in fluid communication with the outlets 12 of these servers 10 through the second manifold 50.

In this embodiment, the server cabinet 1 may further include a first pressure sensor 60 and a second pressure sensor 70. The first pressure sensor 60 and the second pressure sensor 70 are configured to measure the pressures of the inlets 11 and the outlets 12 of the servers 10, respectively. For example, the first pressure sensor 60 is disposed in the first manifold 40 and located close to the top of the first manifold 40, and the second pressure sensor 70 is disposed in the second manifold 50 and located close to the top of the second manifold 50.

The main controller 30 is electrically connected to the fluid driver 20, the first pressure sensor 60, and the second pressure sensor 70.

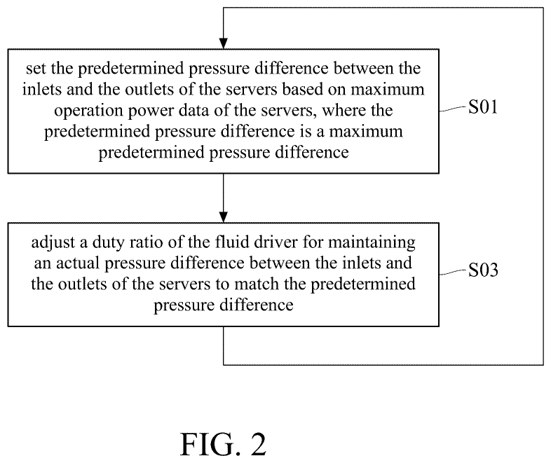

The following paragraphs will introduce a coolant flow rate control method cooperated with the server cabinet 1. Referring to FIG. 1 and FIG. 2. FIG. 2 is a flowchart of a coolant flow rate control method that could cooperate with the server cabinet in FIG. 1.

First, the step of setting a predetermined pressure difference between the inlets 11 and the outlets 12 of the servers 10 based on power data of the servers is performed. For example, the step of setting a predetermined pressure difference between the inlets 11 and the outlets 12 of the servers 10 based on power data of the servers includes a step S01. The step S01 is to set the predetermined pressure difference between the inlets 11 and the outlets 12 of the servers 10 based on maximum operation power data of the servers 10, where the predetermined pressure difference is a maximum predetermined pressure difference.

Furthermore, the main controller 30 of this embodiment is not electrically connected to the servers 10. The predetermined pressure difference between the inlets 11 and the outlets 12 of the servers 10 set by the main controller 30 is based on, for example, the maximum operation power data of the servers 10 at a full load state which are manually given, and the predetermined pressure difference is a maximum predetermined pressure difference. Assuming that the cabinet accommodates three servers 10, a heat source 13 (e.g., CPU or graphic processing unit, GPU) in each server 10 operates in a maximum power, the predetermined pressure difference is set to 100 Kpa, the duty ratio of the fluid driver 20 is 100%, and a total flow rate of the coolant output by the fluid driver 20 is 100 LPM (liter per minute), the flow rate of the coolant through each server 10 is 33.3 LPM, and the heat source 13 in each server 10 can operate in an appropriate temperature.

Next, a Step S03 is performed to adjust a duty ratio of the fluid driver 20 for maintaining an actual pressure difference between the inlets 11 and the outlets 12 of the servers 10 to match the predetermined pressure difference. For example, the main controller 30 adjusts the duty ratio of the fluid driver 20 to match the actual pressure difference between the inlets 11 and the outlets 12 of the servers 10 to the predetermined pressure difference. The actual pressure difference is the difference between the pressures measured by the first pressure sensor 60 and the second pressure sensor 70. The actual pressure difference matches the predetermined pressure difference, which means that the actual pressure difference is equal to the predetermined pressure difference, or the actual pressure difference falls within a range of the predetermined pressure difference plus and minus a predetermined value.

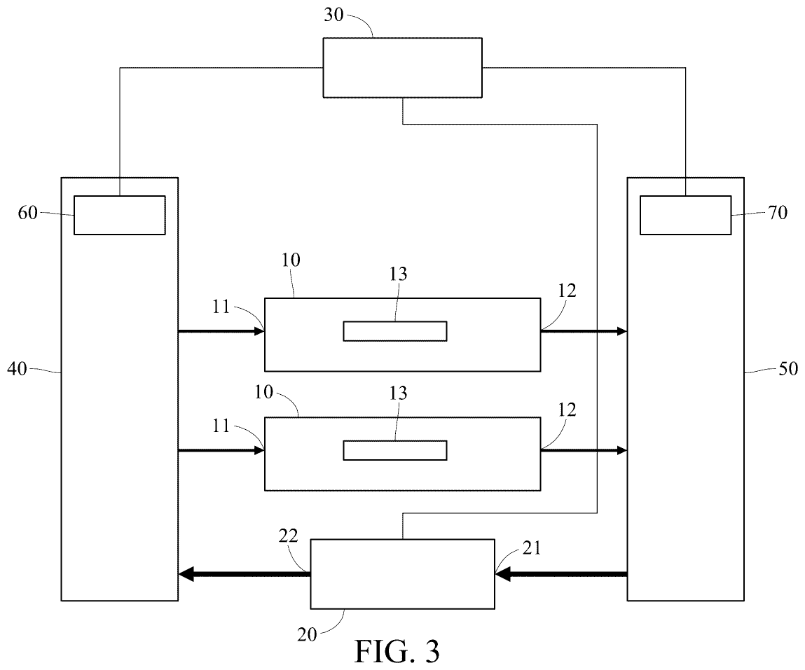

For further illustration, referring to FIG. 3. FIG. 3 is a schematic diagram of the server cabinet in FIG. 1 when one of the servers is removed. Assuming that one of the servers 10 is removed from the cabinet for maintenance, the actual pressure difference between the inlets 11 and the outlets 12 of the remaining servers 10 will inevitably be changed and may not match the predetermined pressure difference. In order to restore the actual pressure difference between the inlets 11 and the outlets 12 of these servers 10 to match the predetermined pressure difference, the main controller 30 will adjust the duty ratio of the fluid driver 20 for maintaining the actual pressure difference between the inlets 11 and the outlets 12 of these servers 10 to match the predetermined pressure difference.

Referring to Table 1. Table 1 shows a comparison between the constant pressure difference control manner of this embodiment and a conventional constant flow rate control manner when the number of the servers 10 is reduced. The constant pressure difference control manner of this embodiment is the aforementioned step of maintaining the actual pressure difference between the inlets 11 and the outlets 12 of these servers 10 to match the predetermined pressure difference, and the conventional constant flow rate control manner refers to maintain the total flow rate of the coolant output by the fluid driver 20.

In Table 1, Scenario A is a reference, the data in Scenario A are expressed as 100%, and the data in Scenario B are percentage values compared to the data in Scenario A.

TABLE 1

| | Scenario | | | |
|---|---|---|---|---|
| | A: Connecting three servers | | B: Connecting two servers | |
| | Constant | | Constant | |
| | pressure | Constant flow | pressure | Constant flow |
| Control manner | difference | rate | difference | rate |
| Pressure difference | 100% | | 100% | 150% |
| between inlets and | | | | |
| outlets of servers | | | | |
| Total flow rate of | 100% | | 66% | 100% |
| coolant output from | | | | |
| fluid driver | | | | |
| Duty ratio of fluid | 100% | | 80% | 115% |
| driver | | | | |

As shown in Table 1, in the constant pressure difference control manner of this embodiment, the main controller 30 reduces the duty ratio of the fluid driver 20, for example, from 100% to 80%, such that the total flow rate of the coolant output from the fluid driver 20, for example, decreases from 100% to 66% for restoring the actual pressure difference between the inlets 11 and the outlets 12 of these servers 10 to match the predetermined pressure difference. As for the conventional constant flow rate control manner, the pressure difference between the inlets and the outlets of the servers increases to 150%, and the duty ratio of the fluid driver 20 increases to 115%.

As a result, when the number of servers 10 is reduced due to maintenance, the flow rate of the coolant output by the fluid driver 20 can be reduced by decreasing the duty ratio of the fluid driver 20 for matching the actual pressure difference between the inlets 11 and outlets 12 of those servers 10 and the predetermined pressure difference, such that the power consumption of the fluid driver 20 can be reduced compared with the conventional constant flow rate control manner, thereby saving energy.

After the step S03 is finished, the step S01 is performed again.

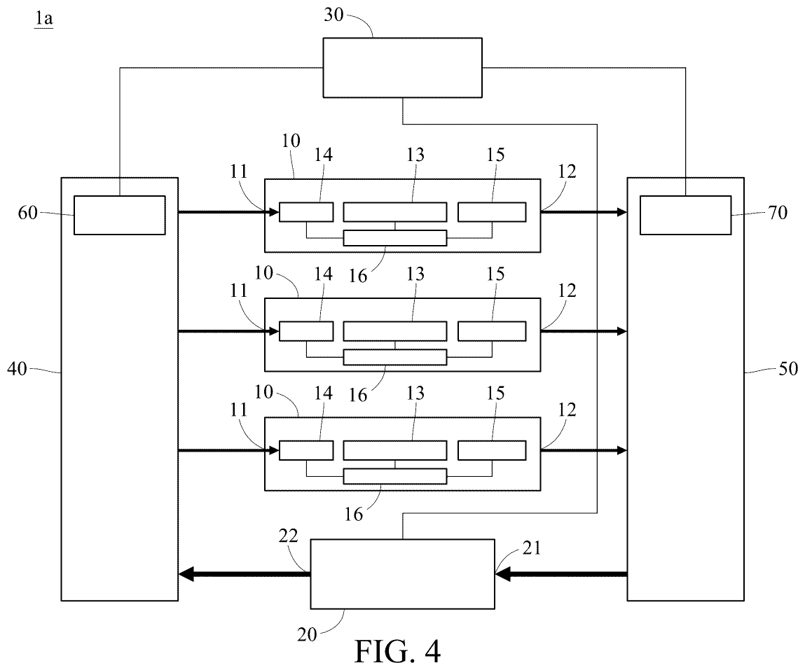

Then, referring to FIG. 4, FIG. 4 is a schematic diagram of a server cabinet according to a second embodiment of the disclosure.

The server cabinet 1a of this embodiment is similar to the server cabinet 1 of the previous embodiment. The following mainly describes the differences between them, and the same parts can refer to the descriptions in the above paragraphs and will not be repeatedly introduced hereinafter.

In this embodiment, each of these servers 10 has a proportional valve 14 disposed at the inlet 11, a temperature sensor 15 and a baseboard management controller 16. The temperature sensor 15 is configured to measure the temperature of the heat source 13, and the baseboard management controller 16 is electrically connected to the proportional valve 14, the heat source 13, and the temperature sensor 15.

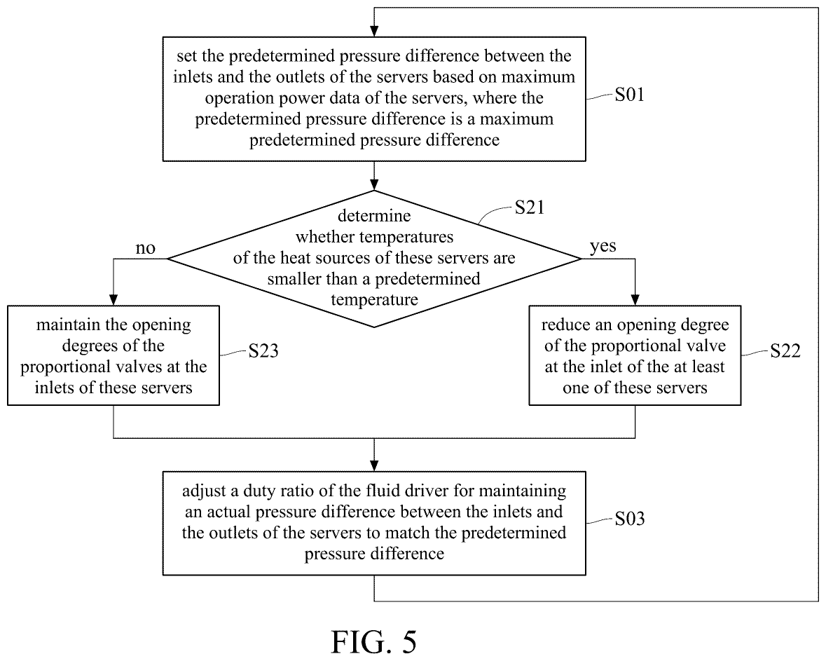

Next, referring to FIGS. 4 and 5, FIG. 5 is a flowchart of a coolant flow rate control method that could cooperate with the server cabinet in FIG. 4.

In addition to the above steps S01 and S03, the coolant flow rate control method further includes steps S21 to S23, which may be arranged between the steps S01 and S03. In other words, after the step S01 is performed to set the predetermined pressure difference between the inlets 11 and the outlets 12 of the servers 10 based on maximum operation power data of the servers 10, where the predetermined pressure difference is a maximum predetermined pressure difference, the step S21 is performed to determine whether temperatures of the heat sources 13 of these servers 10 are smaller than a predetermined temperature. When the temperature of the heat source 13 of at least one of these servers 10 is smaller than the predetermined temperature, the step S22 is performed to reduce an opening degree of the proportional valve 14 at the inlet 11 of the at least one of these servers 10, and then the step S03 is performed to adjust the duty ratio of the fluid driver 20 for maintaining the actual pressure difference between the inlets 11 and the outlets 12 of these servers 10 to match the predetermined pressure difference.

For example, assuming that the number of these servers 10 is three, the heat source 13 (e.g., CPU or GPU) in each server 10 operates in a maximum power, the opening degree of the proportional valve 14 in each server 10 is 100%, the predetermined pressure difference is set to 100 Kpa, the duty ratio of the fluid driver 20 is 100%, and the total flow rate of coolant output from the fluid driver 20 is 100 LPM, the flow rate of coolant through each server 10 is 33.3 LPM, and the heat source 13 in each server 10 can operate in an appropriate temperature.

In a case that two of the servers 10 change from the full load state to a non-full load state (e.g., an idle state), the powers of the heat sources 13 of the two servers 10 are reduced, for example, a half, and the temperatures of the heat sources 13 are thereby reduced to, for example, about 80% of the original temperature. Once the baseboard management controllers 16 of the two servers 10 determine that the temperatures of the heat sources 13 transmitted by the temperature sensors 15 are smaller than the predetermined temperature, it indicates that the heat sources 13 of the two servers 10 are overly cooled by the coolant. At this moment, the baseboard management controllers 16 of the two servers 10 adjust the opening degrees of the proportional valves 14 (e.g., adjust the opening degrees of the proportional valves 14 to 50%). As for the other server 10, the temperature of the heat source 13 of this server 10 is substantially maintained to be its original temperature because the heat source 13 of this server 10 is still at the full load state. Therefore, the baseboard management controller 16 of this server 10 still maintains the opening degree of the proportional valve 14 to be 100%.

After the opening degrees of the proportional valves 14 of the two servers 10 are adjusted, the actual pressure difference between the inlets 11 and the outlets 12 of these servers 10 will change and may not match the predetermined pressure difference. When the main controller 30 determines that the actual pressure difference between the inlets 11 and the outlets 12 of these servers 10 does not match the predetermined pressure difference by the pressures transmitted from the first pressure sensor 60 and second pressure sensor 70, the main controller 30 will adjust the duty ratio of the fluid driver 20 to restore the actual pressure difference between the inlets 11 and the outlets 12 of these servers 10 to match the predetermined pressure difference.

In detail, the main controller 30 will reduce the duty ratio of the fluid driver 20, for example, from 100% to 80%, such that the total flow rate of the coolant output from the fluid driver 20 is reduced, for example, from 100 LPM to 66 LPM. At this moment, since the opening degrees of the proportional valves 14 of two of the three servers 10 are, for example, 50%, and the opening degree of the proportional valve 14 of the other server 10 is, for example, 100%, the flow rate of the coolant through the two servers 10 with the proportional valves 14 of 50% opening degree, for example, 16.7 LPM, and the flow rate of the coolant through the server 10 with the proportional valve 14 of 100% opening degree is, for example, 33.3 LPM. As a result, the actual pressure difference between the inlets 11 and the outlets 12 of these servers 10 is restored to match the predetermined pressure difference.

In another example, when all servers 10 change from the full load state to the non-full load state, the temperatures of the heat sources 13 of these servers 10 will decrease. Once the baseboard management controllers 16 of these servers 10 determines that the temperatures of the heat sources 13 transmitted by the temperature sensors 15 are smaller than the predetermined temperature, it means that the heat sources 13 of these servers 10 are overly cooled by the coolant. At this moment, the baseboard management controllers 16 of these servers 10 adjust the opening degrees of the proportional valves 14 (e.g., adjusting opening degrees of the proportional valves 14 to 50%).

After the opening degrees of the proportional valves 14 of these servers 10 are adjusted, the actual pressure difference between the inlets 11 and the outlets 12 of these servers 10 will be changed and may not match the predetermined pressure difference. When the main controller 30 determines that the actual pressure difference between the inlets 11 and the outlets 12 of these servers 10 does not match the predetermined pressure difference by the pressures transmitted from the first pressure sensor 60 and the second pressure sensor 70, the main controller 30 will adjust the duty ratio of the fluid driver 20 to restore the actual pressure difference between the inlets 11 and the outlets 12 of these servers 10 to match the predetermined pressure difference.

In detail, the main controller 30 will reduce the duty ratio of the fluid driver 20, for example, from 100% to 75%, such that the total flow rate of the coolant output from the fluid driver 20 is reduced, for example, from 100 LPM to 50 LPM. At this moment, since the opening degree of the proportional valve 14 of each of these servers 10 is, for example, 50%, the flow rate of the coolant flowing through each of the servers 10 is, for example, 16.7 LPM. As a result, the actual pressure difference between the inlets 11 and the outlets 12 of these servers 10 is restored to match the predetermined pressure difference.

Referring to Table 2, Table 2 shows the comparison between the constant pressure difference control manner with regulating the opening degrees of the proportional valves in this embodiment and the conventional constant flow rate control manner when the loadings of the servers 10 change.

In Table 2, Scenario A is a reference, the data in Scenario A are expressed as 100%, and the data in Scenarios B and C are percentage values compared to the data in Scenario A.

TABLE 2

| | Scenario | | | | | |
|---|---|---|---|---|---|---|
| | A: All servers are | | B: Two of servers are | | C: All servers are | |
| | at full load | | not at full load | | not at full load | |
| | Constant | | Constant | | Constant | |
| | pressure | | pressure | | pressure | |
| | difference | | difference | | difference | |
| | control | | control | | control | |
| | manner with | | manner with | | manner with | |
| | regulating | | regulating | | regulating | |
| | opening | | opening | | opening | |
| | degrees of | Constant | degrees of | Constant | degrees of | Constant |
| Control | proportional | flow | proportional | flow | proportional | flow |
| manner | valves | rate | valves | rate | valves | rate |
| Pressure | 100% | | 100% | 100% | 100% | 100% |
| difference | | | | | | |
| between | | | | | | |
| inlets and | | | | | | |
| outlets of | | | | | | |
| servers | | | | | | |
| Total flow | 100% | | 66% | 100% | 50% | 100% |
| rate of | | | | | | |
| coolant | | | | | | |
| output | | | | | | |
| from fluid | | | | | | |
| driver | | | | | | |
| Duty ratio | 100% | | 80% | 100% | 75% | 100% |
| of fluid | | | | | | |
| driver | | | | | | |

As shown in Table 2, in Scenario B of the constant pressure difference control manner of this embodiment with regulating the opening degrees of the proportional valves, the main controller 30 reduces the duty ratio of the fluid driver 20, for example, from 100% to 80%, such that the total flow rate of the coolant output from the fluid driver 20, for example, decreases from 100% to 66% for restoring the actual pressure difference between the inlets 11 and the outlets 12 of these servers 10 to match the predetermined pressure difference. In Scenario C, the main controller 30 reduces the duty ratio of the fluid driver 20, for example, from 100% to 75%, such that the total flow rate of the coolant output from the fluid driver 20 decreases, for example, from 100% to 50% for restoring the actual pressure difference between the inlets 11 and the outlets 12 of these servers 10 to match the predetermined pressure difference. In the conventional constant flow rate control manner, even if at least one of the servers is in the non-full load state, the duty ratio of the fluid driver 20 does not change since the total flow rate of the coolant is constant. As a result, the coolant flow rate control method of this embodiment allows the duty ratio of the fluid driver 20 to reduce to, for example, 80% and 75% in scenarios B and C, respectively, thereby reducing about 20% of the power consumption of the fluid driver 20. Accordingly, in a case that the power of the heat source 13 of at least one of the servers 10 decreases, the opening degree of the proportional valve 14 of this server 10 can be adjusted by determining that the temperature of the heat source 13 of this server 10 is smaller than the predetermined temperature, and the actual pressure difference between the inlets 11 and the outlets 12 of the servers 10 can be maintained to match to the predetermined pressure difference, such that the power consumption of the fluid driver 20 can be reduced compared with the conventional constant flow rate control manner, thereby saving energy.

In the step S21, if the temperatures of the heat sources 13 of these servers 10 are not smaller than the predetermined temperature, the step S23 is performed to maintain the opening degrees of the proportional valves 14 at the inlets 11 of these servers 10. After the step S23 is finished, the step S03 is performed.

It should be noted that the step S21 is not limited to be performed after the step S01. In other embodiments, the step S21 and the step S01 may be performed simultaneously, or the step S21 may be performed before the step S01.

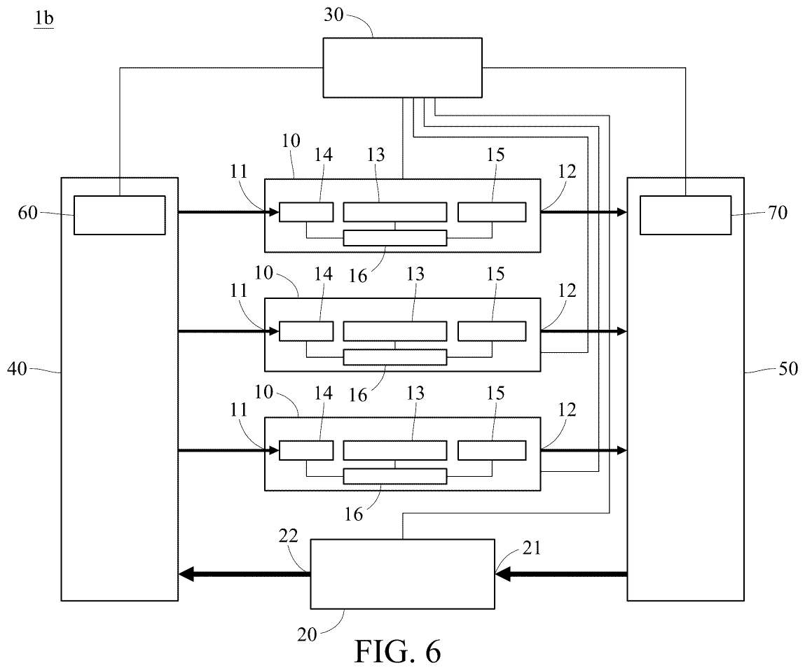

Next, referring to FIG. 6, FIG. 6 is a schematic diagram of a server cabinet according to a third embodiment of the disclosure.

The server cabinet 1b of this embodiment is similar to the server cabinet 1 of the previous embodiment, and the following mainly describes the differences between them, and the same parts can refer to the descriptions in the above paragraphs and will not be repeatedly introduced hereinafter.

In this embodiment, the main controller 30 is electrically connected to these servers 10 and can obtain current power data for these heat sources 13 of these servers 10.

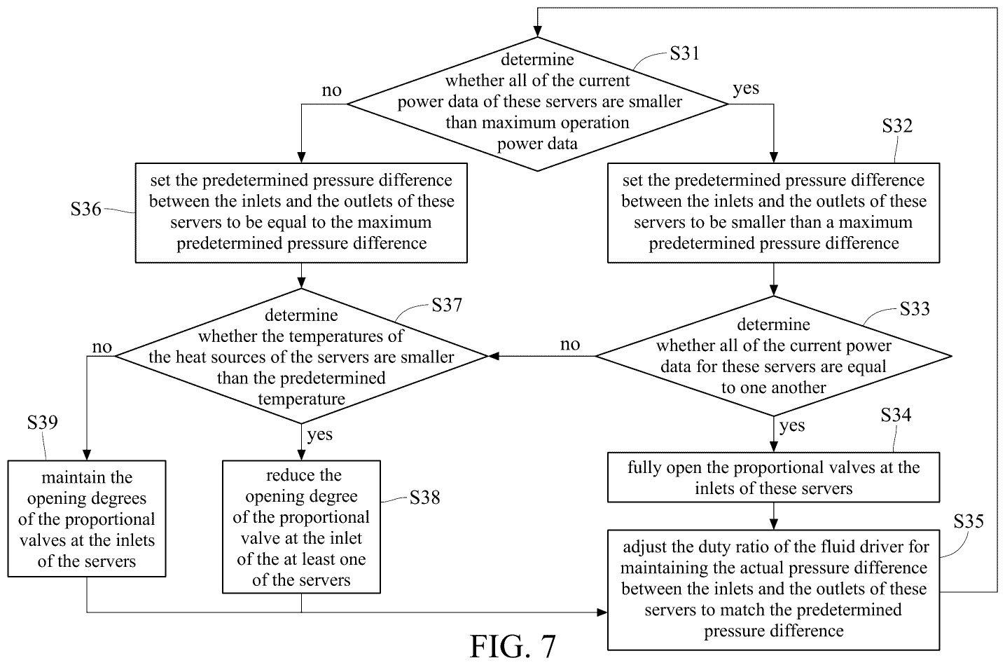

Next, referring to FIGS. 6 and 7, FIG. 7 is a flowchart of a coolant flow rate control method cooperated with the server cabinet in FIG. 6.

In the coolant flow rate control method, the first step is to set a predetermined pressure difference between the inlets 11 and the outlets 12 of these servers 10 based on power data of these servers 10, where the aforementioned step includes setting the predetermined pressure difference between the inlets 11 and the outlets 12 of these servers 10 based on the current power data of these servers 10. For example, the aforementioned step includes step S31: determining whether all of the current power data of these servers 10 are smaller than maximum operation power data. If yes, a step S32 is performed to set the predetermined pressure difference between the inlets 11 and the outlets 12 of these servers 10 to be smaller than a maximum predetermined pressure difference.

In detail, the maximum operation power data are set to the powers of these servers 10 when they operate in the full load state. When the main controller 30 determines that the current power data of all of these servers 10 are smaller than the maximum operation power data, it can be understood that all of these servers 10 are not in the full load state. Thus, the main controller 30 does not require to set the predetermined pressure difference to the maximum predetermined pressure difference, but set the predetermined pressure difference to be smaller than the maximum predetermined pressure difference.

After the step S32, a step S33 is performed to determine whether all of the current power data for these servers 10 are equal to one another. If yes, a step S34 is performed to fully open the proportional valves 14 at the inlets 11 of these servers 10. Next, a step S35 is performed to adjust the duty ratio of the fluid driver 20 for maintaining the actual pressure difference between the inlets 11 and the outlets 12 of these servers 10 to match the predetermined pressure difference.

Taking an example to illustrate the steps S31 to S35, assuming that the number of the servers 10 is three, the heat source 13 in each server 10 operates in a maximum power, the opening degree of the proportional valve 14 in each server 10 is 100%, the predetermined pressure difference is set to the maximum predetermined pressure difference (e.g., 100 Kpa), the duty ratio of the fluid driver 20 is set to 100%, and the total flow rate of the coolant output from the fluid driver 20 is 100 LPM, the flow rate of the coolant through each server 10 is 33.3 LPM, and the heat sources 13 in the servers 10 can operate in an appropriate temperature. In a case that the heat sources 13 in the servers 10 change to operate in same powers smaller than the maximum power (i.e., the current power data of these servers 10 are equal to each other and are smaller than the maximum operation power data), the main controller 30 sets the predetermined pressure difference (e.g., 42 Kpa) between the inlets 11 and the outlets 12 of these servers 10 to be smaller than the maximum predetermined pressure difference (e.g., 100 Kpa), and the main controller 30 fully open the proportional valves 14 via the baseboard management controllers 16 of these servers 10. In order to maintain the actual pressure difference between the inlets 11 and the outlets 12 of these servers 10 to match the predetermined pressure difference, the duty ratio of the fluid driver 20 is adjusted to be, for example, 60% by the main controller 30, and the total flow rate of the coolant output from the fluid driver 20 is, for example, 50 LPM. At this moment, since the opening degrees of the proportional valves 14 of these servers 10 are equal to one another, the flow rate of the coolant through each server 10 is, for example, 16.7 LPM.

Referring to Table 3, Table 3 shows the comparison between the constant pressure difference control manner after adjusting pressure difference in this embodiment and the conventional constant flow rate control manner when the power load of the server 10 is changed. In Table 3, Scenario A is a reference, the data in Scenario A are expressed as 100%, and the data in Scenario B are percentage values compared to the data in Scenario A.

TABLE 3

| | Scenario | | | |
|---|---|---|---|---|
| | A: All servers are at full load | | B: All servers are not at full load | |
| | Constant | | Constant | |
| | pressure | | pressure | |
| | difference | | difference | |
| | control manner | | control manner | |
| | after adjusting | | after adjusting | |
| | pressure | Constant flow | pressure | Constant flow |
| Control manner | difference | rate | difference | rate |
| Pressure | 100% | | 42% | 100% |
| difference | | | | |
| between inlets | | | | |
| and outlets of | | | | |
| servers | | | | |
| Total coolant | 100% | | 50% | 100% |
| flow output | | | | |
| from fluid | | | | |
| driver | | | | |
| Duty ratio of | 100% | | 60% | 100% |
| fluid driver | | | | |

As shown in Table 3, in Scenario B of the constant pressure difference control manner after adjusting pressure difference in this embodiment, the main controller 30 reduces the predetermined pressure difference between the inlets 11 and the outlets 12 of these servers 10 to, for example, 42%, the main controller 30 reduces the duty ratio of the fluid driver 20 from, for example, 100% to 60%, such that the total flow rate of the coolant output from the fluid driver 20 decreases from, for example, 100% to 50% for matching the actual pressure difference between the inlets 11 and the outlets 12 of these servers 10 and the reduced predetermined pressure difference. In the conventional constant flow rate control manner, even if the servers are not in the full load state, the duty ratio of the fluid driver 20 does not change since the total flow rate of the coolant is constant. As a result, in a case that the main controller 30 determines that the heat sources 13 of all the servers 10 are not in the full load state, setting the predetermined pressure difference between the inlets 11 and the outlets 12 of these servers 10 to be less than the maximum predetermined pressure difference and making the actual pressure difference between the inlets 11 and the outlets 12 of these servers 10 to match the predetermined pressure difference can reduce the power consumption of the fluid driver 20 compared with the conventional constant flow rate control manner, thereby saving energy.

In step S31, when the current power data of these servers 10 are determined to be not all smaller than the maximum operation power data, a step S36 is performed to set the predetermined pressure difference between the inlets 11 and the outlets 12 of these servers 10 to be equal to the maximum predetermined pressure difference. Then, a step S37 is performed to determine whether the temperatures of the heat sources 13 of the servers 10 are smaller than the predetermined temperature.

In step S33, when the current power data of the servers 10 are not equal to one another, the step S37 is performed determine whether the temperatures of the heat sources 13 of the servers 10 are smaller than the predetermined temperature.

In step S37, When the temperature of the heat source 13 of at least one of the servers 10 is smaller than the predetermined temperature, a step S38 is performed to reduce the opening degree of the proportional valve 14 at the inlet 11 of the at least one of the servers 10. Then, the step S35 is performed to adjust the duty ratio of the fluid driver 20 for maintaining the actual pressure difference between the inlets 11 and the outlets 12 of the servers 10 to match the predetermined pressure difference.

In step S37, when the temperatures of the heat sources 13 of the servers 10 are not smaller than the predetermined temperature, a step S39 is performed to maintain the opening degrees of the proportional valves 14 at the inlets 11 of the servers 10. After step S39 is finished, the step S35 is performed.

The aforementioned steps S36, S37, S38, and S39 are the same as the steps S01, S21, S22, and S23, and thus the details of the steps S36, S37, S38, and S39 will not be described repeatedly and can refer to the descriptions in the above paragraphs.

Note that step S32 is not limited to be performed when the current power data of these servers 10 are all smaller than the maximum operation power data. In other embodiments, the step S32 may be performed when at least part of the current power data of these servers 10 is smaller than the maximum operation power data. In such a case, the step S36 will be performed when the current power data of these servers 10 are all not smaller than the maximum operation power data.

In addition, the step S34 is not limited to fully opening the proportional valves 14 at the inlets 11 of the servers 10. In other embodiments, the step S34 may be modified to set the opening degrees of the proportional valves at the inlets of these servers to a predetermined opening degree, where the predetermined opening degree may be any value from 1% to 100%.

Furthermore, the step S33 and the step S34 are optional steps. In other embodiments, the step S33 and the step S34 may be omitted, and after the step S32 is performed, the step S37 may be performed directly. In addition, the step S37 is not limited to being performed after the step S31 is finished. In other embodiments, the step S37 and the step S31 may be performed simultaneously, or the step S37 may be performed before the step S31.

According to the coolant flow rate control method and server cabinet disclosed in the above embodiments, the flow rate of the coolant output by the fluid driver can be reduced by adjusting the duty ratio of the fluid driver for matching the actual pressure difference between the inlets and the outlets of the servers with the predetermined pressure difference, which reduces the power consumption of the fluid driver, thereby saving energy.

In addition, in a case that the power of the heat source of at least part of the servers decreases, the opening degree of the proportional valve of this server can be adjusted by determining that the temperature of the heat source of this server is smaller than the predetermined temperature, and the actual pressure difference between the inlets and the outlets of these servers can be maintained to match to the predetermined pressure difference, such that the power consumption of the fluid driver can be reduced compared with the conventional constant flow rate control manner, thereby saving energy.

In a case that the main controller determines that the heat sources of all servers are not in the full load, setting the predetermined pressure difference between the inlets and the outlets of these servers to be less than the maximum predetermined pressure difference, and making the actual pressure difference between the inlets and the outlets of these servers to match the predetermined pressure difference can reduce the power consumption of the fluid driver compared with the conventional constant flow rate control manner, thereby saving energy.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A coolant flow rate control method, configured to be applied to a plurality of servers and a fluid driver in fluid communication with the plurality of servers, comprising:
setting a predetermined pressure difference between inlets and outlets of the plurality of servers based on power data of the plurality of servers; and
adjusting a duty ratio of the fluid driver for maintaining an actual pressure difference between the inlets and the outlets of the plurality of servers to match the predetermined pressure difference.

2. The coolant flow rate control method according to claim 1, wherein the step of setting the predetermined pressure difference between the inlets and the outlets of the plurality of servers based on the power data of the plurality of servers comprises setting the predetermined pressure difference between the inlets and the outlets of the plurality of servers based on maximum operation power data of the plurality of servers, and the predetermined pressure difference is a maximum predetermined pressure difference.

3. The coolant flow rate control method according to claim 2, further comprising:
determining whether temperatures of heat sources of the plurality of servers are smaller than a predetermined temperature;
if the temperature of the heat source of at least one of the plurality of servers is smaller than the predetermined temperature, reducing an opening degree of a proportional valve at the inlet of the at least one of the plurality of servers, and performing the step of adjusting the duty ratio of the fluid driver for maintaining the actual pressure difference between the inlets and the outlets of the plurality of servers to match the predetermined pressure difference.

4. The coolant flow rate control method according to claim 3, wherein the step of determining whether the temperatures of the heat sources of the plurality of servers are smaller than the predetermined temperature is performed after the step of setting the predetermined pressure difference between the inlets and the outlets of the plurality of servers based on the maximum operation power data of the plurality of servers.

5. The coolant flow rate control method according to claim 1, wherein the step of setting the predetermined pressure difference between the inlets and the outlets of the plurality of servers based on the power data of the plurality of servers comprises setting the predetermined pressure difference between the inlets and the outlets of the plurality of servers based on current power data of the plurality of servers, and comprises:
determining whether at least part of the current power data of the plurality of servers is smaller than maximum operation power data;
if yes, setting the predetermined pressure difference to be smaller than a maximum predetermined pressure difference.

6. The coolant flow rate control method according to claim 5, wherein the step of determining whether at least part of the current power data of the plurality of servers is smaller than the maximum operation power data comprises determining whether all of the current power data of the plurality of servers are smaller than the maximum operation power data.

7. The coolant flow rate control method according to claim 6, wherein if the current power data of the plurality of servers are not all smaller than the maximum operation power data, setting the predetermined pressure difference to be equal to the maximum predetermined pressure difference.

8. The coolant flow rate control method according to claim 5, further comprising:
determining whether temperatures of heat sources of the plurality of servers are smaller than a predetermined temperature;
if the temperature of the heat source of at least one of the plurality of servers is smaller than the predetermined temperature, reducing an opening degree of a proportional valve at the inlet of the at least one of the plurality of servers, and performing the step of adjusting the duty ratio of the fluid driver for maintaining the actual pressure difference between the inlets and the outlets of the plurality of servers to match the predetermined pressure difference.

9. The coolant flow rate control method according to claim 8, wherein the step of determining whether the temperatures of the heat sources of the plurality of servers are smaller than the predetermined temperature is performed after the step of setting the predetermined pressure difference between the inlets and the outlets of the plurality of servers based on the current power data of the plurality of servers.

10. The coolant flow rate control method according to claim 8, after the step of setting the predetermined pressure difference to be smaller than the maximum predetermined pressure difference, further comprising:
determining whether the current power data of the plurality of servers are equal to one another;
if yes, fully opening proportional valves at the inlets of the plurality of servers, and performing the step of adjusting the duty ratio of the fluid driver for maintaining the actual pressure difference between the inlets and the outlets of the plurality of servers match the predetermined pressure difference; and
if not, performing the step of determining whether the temperatures of the heat sources of the plurality of servers are smaller than the predetermined temperature.

11. The coolant flow rate control method according to claim 1, wherein the power data of the plurality of servers comprises current power data of the plurality of servers or maximum operation power data of the plurality of servers.

12. A server cabinet, comprising:
a plurality of servers, wherein the plurality of servers are connected in parallel to each other, and each of the plurality of servers has an inlet and an outlet;
a fluid driver, in fluid communication with the plurality of servers; and
a main controller, electrically connected to the fluid driver;
wherein the main controller is configured to set a predetermined pressure difference between the inlets and the outlets of the plurality of servers based on power data of the plurality of servers and adjust a duty ratio of the fluid driver for maintaining an actual pressure difference between the inlets and the outlets of the plurality of servers to match the predetermined pressure difference.

13. The server cabinet according to claim 12, wherein the main controller is configured to set the predetermined pressure difference between the inlets and the outlets of the plurality of servers based on maximum operation power data of the plurality of servers, and the predetermined pressure difference is a maximum predetermined pressure difference.

14. The server cabinet according to claim 13, wherein each of the plurality of servers comprises a proportional valve disposed at the inlet, a heat source, a temperature sensor, and a baseboard management controller, the temperature sensor is configured to measure a temperature of the heat source, and the baseboard management controller is electrically connected to the proportional valve, the heat source, and the temperature sensor; when the baseboard management controller of at least one of the plurality of servers determines that the temperature of the heat source is smaller than a predetermined temperature, the baseboard management controller of the at least one of the plurality of servers reduces an opening degree of the proportional valve at the inlet, and the main controller adjusts the duty ratio of the fluid driver for maintaining the actual pressure difference between the inlets and the outlets of the plurality of servers to match the predetermined pressure difference.

15. The server cabinet according to claim 14, wherein after the main controller sets the predetermined pressure difference between the inlets and the outlets of the plurality of servers based on the maximum operation power data of the plurality of servers, the baseboard management controller of each of the plurality of servers determines whether the temperature of the heat source is smaller than the predetermined temperature.

16. The server cabinet according to claim 12, wherein the main controller is electrically connected to the plurality of servers, the main controller is configured to set the predetermined pressure difference between the inlets and the outlets of the plurality of servers based on current power data of the plurality of servers, and the main controller is configured to set the predetermined pressure difference to be smaller than a maximum predetermined pressure difference when at least part of the current power data is smaller than maximum operation power data.

17. The server cabinet according to claim 16, wherein the main controller is configured to set the predetermined pressure difference to be smaller than the maximum predetermined pressure difference when all of the current power data are smaller than the maximum operation power data, and the main controller is configured to set the predetermined pressure difference to be equal to the maximum predetermined pressure difference when the current power data are not all smaller than the maximum operation power data.

18. The server cabinet according to claim 16, wherein each of the plurality of servers comprise a proportional valve disposed at the inlet, a heat source, a temperature sensor, and a baseboard management controller, the temperature sensor is configured to measure a temperature of the heat source, and the baseboard management controller is electrically connected to the proportional valve, the heat source, and the temperature sensor; when the baseboard management controller of at least one of the plurality of servers determines that the temperature of the heat source is smaller than a predetermined temperature, the baseboard management controller of the at least one of the plurality of servers reduces an opening degree of the proportional valve at the inlet, and the main controller adjusts the duty ratio of the fluid driver for maintaining the actual pressure difference between the inlets and the outlets of the plurality of servers to match the predetermined pressure difference.

19. The server cabinet according to claim 18, wherein after the main controller sets the predetermined pressure difference between inlets and outlets of the plurality of servers based on the current power data of the plurality of servers, the baseboard management controller of each of the plurality of servers determines whether the temperature of the heat source is smaller than the predetermined temperature.

20. The server cabinet according to claim 18, wherein after the main controller sets the predetermined pressure difference to be smaller than the maximum predetermined pressure difference, the main controller is configured to fully open the proportional valve at the inlet via the baseboard management controller of each of the plurality of servers when all of the current power data of the plurality of servers are equal to one another, and the main controller is configured to drive the baseboard management controllers of the plurality of servers to determine whether the temperatures of the heat sources are smaller than the predetermined temperature when the current power data of the plurality of servers are not all equal to one another.

21. The server cabinet according to claim 12, further comprising a first pressure sensor and a second pressure sensor, wherein the first pressure sensor and the second pressure sensor are electrically connected to the main controller, and the first pressure sensor and the second pressure sensor are respectively configured to measure pressures of the inlets and the outlets of the plurality of servers, and the actual pressure difference is a difference between the pressures measured by the first pressure sensor and the second pressure sensor.

22. The server cabinet according to claim 21, further comprising a first manifold and a second manifold, wherein an outlet of the fluid driver is connected to the inlets of the plurality of servers via the first manifold, an inlet of the fluid driver is connected to the outlets of the plurality of servers via the second manifold, the first pressure sensor is disposed in the first manifold, and the second pressure sensor is disposed in the second manifold.

23. The server cabinet according to claim 12, wherein the power data of the plurality of servers comprises current power data of the plurality of servers or maximum operation power data of the plurality of servers.
